(19) United States
(12) Patent Application Publication
(10) Pub. No.: US 2021/0104447 A1
(43) Pub. Date: Apr. 8, 2021

(54) SILICON ON DIAMOND THERMAL AND SHIELDING MITIGATION

(71) Applicant: QUALCOMM Incorporated, San Diego, CA (US)

(72) Inventors: Jonghae KIM, San Diego, CA (US); Je-Hsiung LAN, San Diego, CA (US); Ranadeep DUTTA, Del Mar, CA (US)

(21) Appl. No.: 16/592,471

(22) Filed: Oct. 3, 2019

(51) Int. Cl. H01L 23/367; H01L 27/12; H01L 23/552; H01L 23/373; H01L 23/00; H01L 23/48; H01L 21/56

(52) U.S. Cl. CPC H01L 23/3675; H01L 2224/82101; H01L 23/552; H01L 23/3732; H01L 23/3735; H01L 24/05; H01L 24/13; H01L 24/16; H01L 24/24; H01L 24/82; H01L 23/481; H01L 21/56; H01L 2224/05569; H01L 2224/0401; H01L 2224/13021; H01L 2224/16225; H01L 2224/73259; H01L 2224/24011; H01L 2224/24226; H01L 27/1203

(57) ABSTRACT

Active devices in an integrated circuit (IC) die package, such as in a radio frequency front end (RFFE) package can generate significant amount of heat. This problem can become acute especially as the operating frequency is high such as in 5G NR. Also, electromagnetic interference issues can arise in such packages. One or more techniques to mitigate thermal and electrical interference issues in IC die packages are presented.

### FIELD OF DISCLOSURE

The field of the disclosed subject matter relates to panel level packaging. In particular, the field of the disclosed subject matter relates to panel level packaging for silicon on diamond (SOD) thermal and shielding mitigation and to methods of manufacturing the same.

### BACKGROUND

Wireless communication systems have developed through various generations, including a first-generation analog wireless phone service (1G), a second-generation (2G) digital wireless phone service (including interim 2.5G and 2.75G networks), a third-generation (3G) high speed data, Internet-capable wireless service and a fourth-generation (4G) service (e.g., Long Term Evolution (LTE) or WiMax). There are presently many different types of wireless communication systems in use, including Cellular and Personal Communications Service (PCS) systems. Examples of known cellular systems include the cellular Analog Advanced Mobile Phone System (AMPS), and digital cellular systems based on Code Division Multiple Access (CDMA), Frequency Division Multiple Access (FDMA), Time Division Multiple Access (TDMA), the Global System for Mobile access (GSM) variation of TDMA, etc.

In the current fifth-generation (5G) and coming sixth-generation (6G) era, massive wireless communication capability will be in demand. Applications such as autonomous drive, industry internet-of-things (IOT), infotainment, gaming, education, interactive-collaborations with artificial intelligence (AI), and virtual reality (VR), augmented reality (AR), and so on may require substantial speeds in both uplink and downlink, e.g., higher than 10 Gbps. Such speeds may be realized with millimeter wave (mmWave) communications that can offer wider bandwidth.

FIG. 1 illustrates a block diagram of a conventional radio frequency front end (RFFE) module. In this instance, the RFFE module is a low noise amplifier (LNA), power amplifier (PA), filter (FIL) 100 capable of realizing mmWave communications. The LPAF (LNA, PA, FIL) 100 may be a wireless transceiver with upper half being the transmitting portion and the lower half being the receiving portion. The illustrated LPAF 100 includes a switch 110, radio frequency (RF) filters 120, first matching circuits 130, power amplifiers (PA) 140, second matching circuits 150, and LNAs 160.

The components of the LPAF 100 may be hetero-integrated or co-integrated. In hetero-integration, the individual components—e.g., the switch 110, the RF filters 120, the first and second matching circuits 130 and 150, the PAs 140, and the LNAs 160—are initially fabricated as individual devices. Thereafter, the components are assembled and interconnected on a substrate. Unfortunately, this can result in the assembled LPAF 100 being physically large. Also, due to components being individually being fabricated, it can also be expensive. Further, damage can occur during assembly. In addition, signal losses can be more pronounced due to the relative long interconnection distances between the discrete components.

Co-integration addresses some of the issues associated with hetero-integration. In co-integration, the LPAF 100 can be fabricated as a monolithic integrated circuit (IC) that includes all of the components. In other words, the active components (e.g., PA, LNA, switch), passive components (matching circuits, filters), and interconnects may be fabricated in the IC. In mmWave applications, components of different technologies (e.g., CMOS for LNAs and switches, III-V for PAs, etc.) can be integrated into the same IC. With co-integration, the LPAF 100 can be made smaller, with less cost, and can avoid signal losses.

However, co-integration is not without its problems. For example, there can be significant thermal issues. Materials such as Si (e.g., used in CMOS fabrication) and GaAs (e.g., used in III-V fabrication) are typically poor thermal conductors. Thus, there can be significant self-heating, especially on high density components such as the PA. This problem is exasperated in mmWave applications where frequencies are very high meaning that the heat generated by components such as the PA can be especially acute.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

An exemplary package is disclosed. The package may comprise a laminate, an integrated circuit (IC) die on the laminate, a mold on the laminate and on the IC die, and a cage within the mold. The laminate may comprise a laminate redistribution layer (RDL). The IC die may comprise one or more active devices above a lower surface of the IC die and electrically coupled with the laminate RDL through one or more interconnects at the lower surface of the IC die. The IC die may also comprise a thermal spreader on the one or more active devices. The thermal spreader may be thermally conductive and electrically insulative. The mold may be structured to surround side and upper surfaces of the IC die. The cage may be structured to conduct heat generated by the one or more active devices emanating through the thermal spreader above an upper surface of the IC die from an interior of an IC die boundary to an exterior of the IC die boundary.

An exemplary method is disclosed. The method may comprise providing a laminate and providing an integrated circuit (IC) die on the laminate. The laminate may comprise a laminate redistribution layer (RDL). The IC die may comprise one or more active devices above a lower surface of the IC die and electrically coupled with the laminate RDL through one or more interconnects at the lower surface of the IC die. The IC die may also comprise a thermal spreader on the one or more active devices. The thermal spreader may be thermally conductive and electrically insulative. The method may also comprise forming a mold on the laminate and on the IC die such that the mold surrounds side and upper surfaces of the IC die. The method may further comprise forming a cage within the mold such that the cage conducts heat generated by the one or more active devices emanating through the thermal spreader above an upper surface of the IC die from an interior of an IC die boundary to an exterior of the IC die boundary.

Another exemplary method is disclosed. The method may comprise singulating a wafer of integrated circuit (IC) dies into individual IC dies, picking and placing an IC die onto a laminate, and attaching the IC die to the laminate. The IC die may comprise one or more active devices above a lower surface of the IC die, and a thermal spreader on the one or more active devices. The thermal spreader being thermally conductive and electrically insulative. The laminate may comprise a laminate redistribution layer (RDL). The IC die may be attached to the laminate such that the one or more active devices are electrically coupled with the laminate RDL through one or more interconnects at the lower surface of the IC die. The method may also comprise depositing a first mold compound on the IC die and on the laminate, and planarizing the first mold compound to form a side mold part. The upper surface of the IC die may be exposed after planarizing. The method may further comprise forming one or more mold openings in the side mold part, depositing a seed layer, plating a conductive layer on the seed layer, depositing a second mold compound, and planarizing the second mold compound. The seed layer may be deposited in the one or more mold openings and on the IC die. The second mold compound may be deposited on the conductive layer, the IC die, and the side mold part. Planarizing the second mold compound may form a lateral mold part. The seed layer and the plated conductive layer may form a cage comprising a lateral cage part within the lateral mold part and a side cage part within the side mold part. The lateral cage part may be structured to conduct heat generated by the one or more active devices emanating through the thermal spreader above an upper surface of the IC die from an interior of an IC die boundary to an exterior of the IC die boundary. The side cage part may be in contact with the lateral cage part such that the heat conducted to the exterior of the IC die boundary by the lateral cage part is conducted to the laminate by the side cage part.

### BRIEF DESCRIPTION OF THE DRAWINGS

The accompanying drawings are presented to aid in the description of examples of one or more aspects of the disclosed subject matter and are provided solely for illustration of the examples and not limitation thereof.

FIG. 1 illustrates a block diagram of a conventional low noise amplifier, power amplifier, filter module;

FIG. 2 illustrates an example of a RFFE module formed as a monolithic IC device;

FIG. 3 illustrates an example of a conventional RFFE package;

FIG. 4A illustrates an example of a package according to one or more aspects;

FIG. 4B illustrates an example side view of the package of FIG. 4A according to one or more aspects;

FIGS. 4C, 4D, and 4E illustrate example top views of the package of FIG. 4A according to one or more aspects;

FIGS. 5 and 6 illustrate further examples of packages according to one or more aspects;

FIGS. 7A-7H illustrate examples of different stages of fabricating a package according to one or more aspects;

FIGS. 8-13 illustrate flow charts of an example method of fabricating a package according to one or more aspects;

FIG. 14 illustrates a flow chart of another example method of fabricating a package according to one or more aspects; and

FIG. 15 illustrates examples of devices with a package integrated therein.

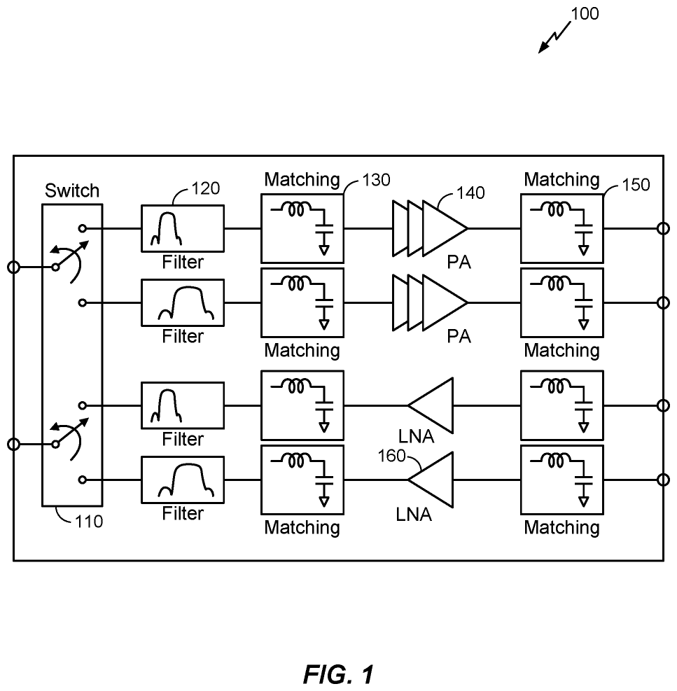

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

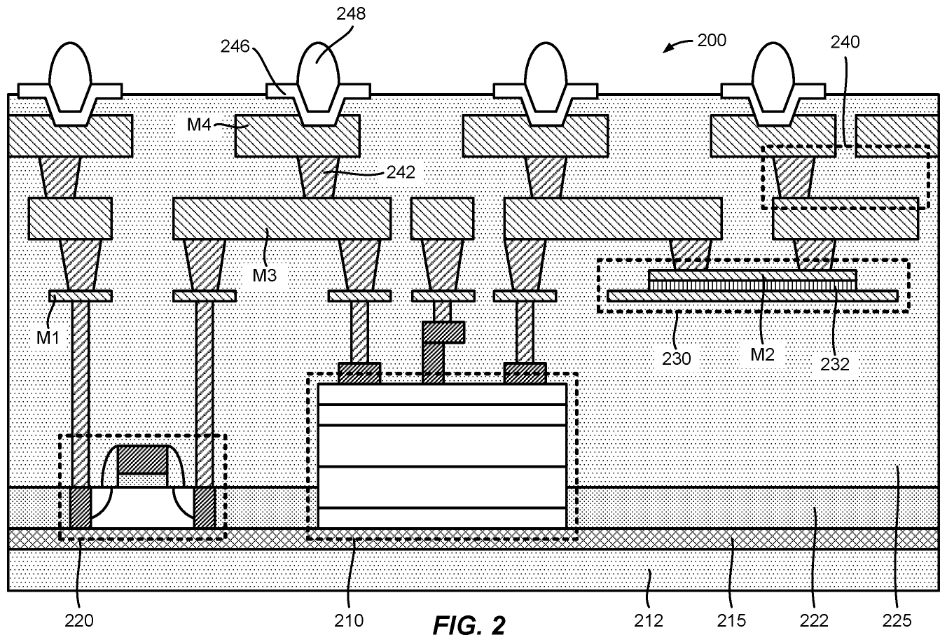

FIG. 2 illustrates a RFFE or LPAF module 200 formed as a monolithic IC device. The RFFE 200 may include a silicon (Si) layer 212, a diamond layer 215 on the Si layer 212, a shallow trench isolation (STI) layer 222 on the diamond layer 215, and a routing layer 225 on the STI layer 222. Before proceeding further, it should be noted that terms such as “on”, “above”, “below”, “upper”, “lower”, “top”, “bottom”, “left”, “right” and so on may be used. Unless indicated otherwise, these are merely as terms of convenience, and should not be taken to be limiting. For example, they should not be taken to indicate absolute orientations.

The RFFE 200 may include active components formed from different fabrication technologies. For example, the RFFE 200 may include a PA 210 and a LNA 220. The PA 210 may be an example of a group III-V active device, and the LNA 220 may be an example of a CMOS (Si-based) active device. While not shown, it is contemplated that there can be any number of group III-V devices and any number of CMOS devices. More generically, there may be one or more first technology (e.g., group III-V) devices and one or more second technology (e.g., CMOS) devices.

The RFFE 200 may also include one or more integrated passive devices (IPDs) such as a metal-insulator-metal (MIM) capacitor 230 and an inductor 240 within the routing layer 225. The routing layer 225 may be filled with an interlayer dielectric (ILD) along with one or more metallization layers and one or more connection layers. In FIG. 2, four metallization layers M1, M2, M3, and M4 and multiple vias 242 are formed within the ILD to form routing path to route signals from/to the active and passive components of the RFFE 200.

As seen, the IPDs 230, 240 may be formed by the metallization layers M1, M2, M3, and M4 and vias 242 within the routing layer. For example, the MIM capacitor 230 may be formed by portions of metallization layers M1 and M2 with a dielectric 232 in between the M1 and M2 layers. Also, inductors 240 may be formed by forming conductive loops using the metallization layers M1, M2, M3, and M4 and vias 242.

The RFFE 200 may include underbump metallizations 246 and bumps (e.g., solder bumps) 248 to enable the components 210, 220, 230, and/or 240 to be connected externally. The IC device 200 may be a flip chip (FC) device, and the view illustrated in FIG. 2 is a view prior to the RFFE 200 being flipped and assembled in a package.

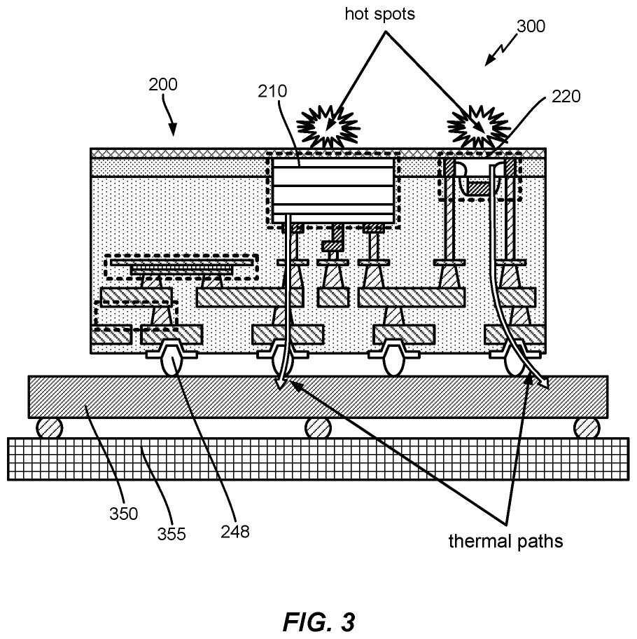

FIG. 3 illustrates an example of a conventional RFFE package 300. The package 300 may include a printed circuit board (PCB) 355 and a laminate 350 on the PCB 355. The package 300 may further include the RFFE 200 of FIG. 2 flipped and attached to the laminate 350. So as to reduce clutter, not all individual components of the RFFE 200 are indicated.

As mentioned above, co-integration addresses some of the issues associated with hetero-integration, but co-integration itself has issues including significant thermal issues. This is illustrated in FIG. 3. In particular, the active devices—e.g., the LNA 220 and the PA 210—can generate significant amounts of heat during operation and thus cause hot spots as shown. In the conventional package 300, the only thermal path is through the metallization layers and vias in the routing layer be dissipated to the laminate 350. Due to BEOL options, the critical lengths of the thermal paths can be extended, and thus degrade thermal efficiency. Also, since the thermal paths are relying only on the BEOL interconnects, there is no solid thermal path. Further, due to lack of compartment shielding, electromagnetic interferences (EMI) can result.

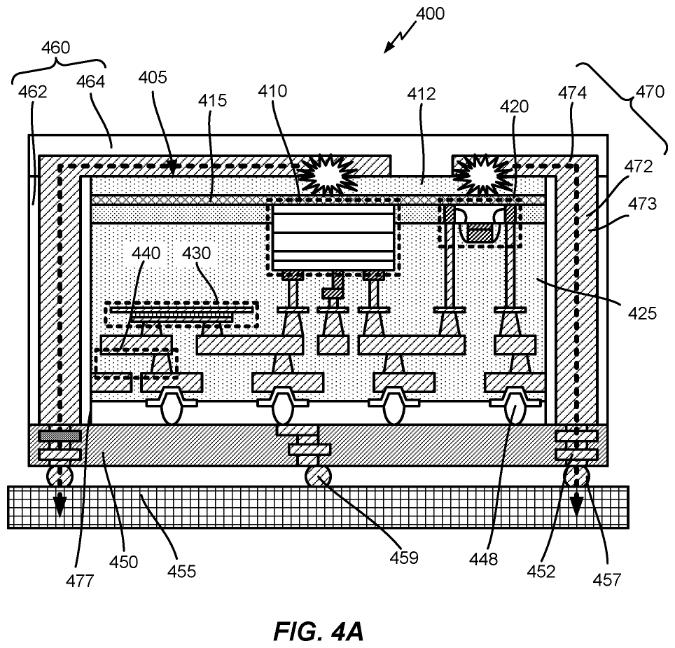

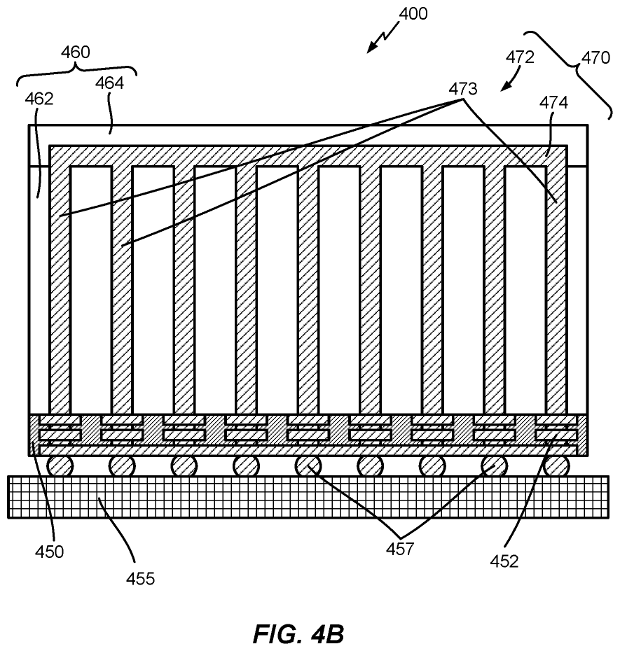

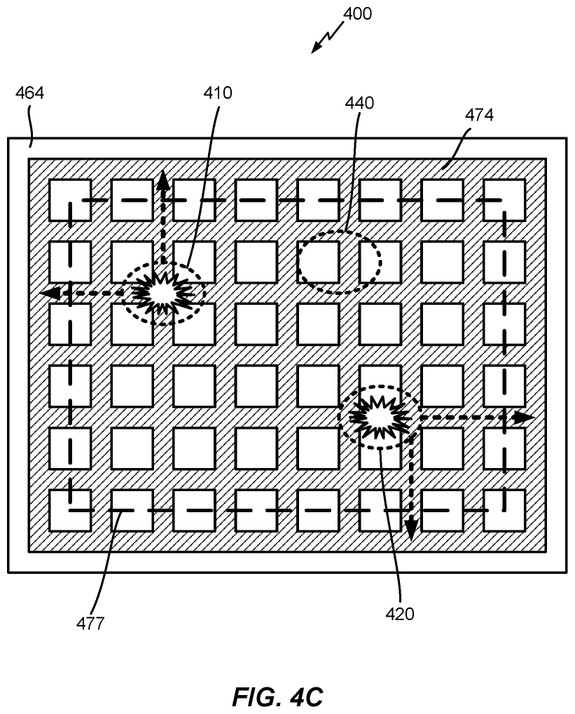

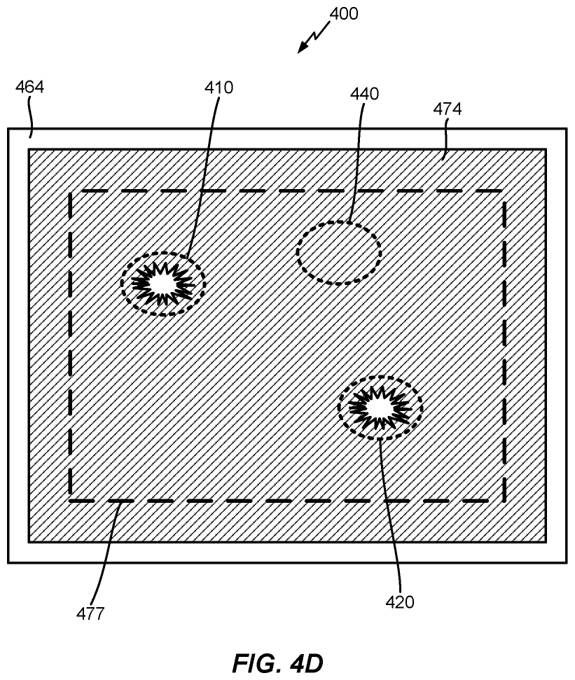

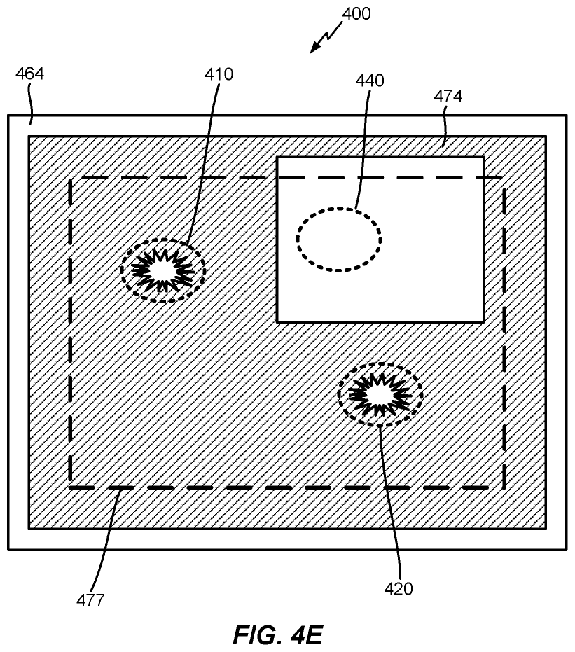

FIG. 4A illustrates an example of a package 400 according to one or more aspects that addresses some or all of the issues associated with the conventional package 300. The package 400 may include an integrated circuit (IC) die 405. Therefore, the package 400 may also be referred to as an IC die package 400. The IC die 405 may be a monolithic IC die and may include one or more active devices 410, 420. The IC die 405 may also include one or more integrated passive devices 430, 440 (e.g., capacitor, inductor). In this instance, it may be assumed that the IC die 405 is a radio frequency front end (RFFE) die. This is merely for illustration purposes, and the aspects disclosed herein may be applicable to IC dies that includes active devices in general.

The one or more active devices 410, 420 may be devices of different technologies. For example, the active device 410 may be a power amplifier (PA) formed of a group III-V based technology and the active device 420 may be a low noise amplifier (LNA) formed of a silicon (Si)-based technology (e.g., CMOS). More generically, the IC die 405 may comprise a first active device (e.g., PA 410) and a second active device (e.g., LNA 420). The first active device may be a device of a first technology and the second active device may be a device of a second technology different from the first technology.

The IC die 405 may be a flipchip device such that one or more interconnects 448 (e.g., solder) extend from a lower surface thereof. The interconnects 448 may be electrically coupled with the active devices 410, 420. As seen, the active devices 410, 420 may be above the lower surface of the IC die 405, and the interconnects 448 and the active devices 410, 420 may be electrically coupled with each other through metallization layers and vias within a routing layer 425 of the IC die 405.

The IC die 405 may be on a laminate 450, and the laminate 450 may be on a printed circuit board (PCB) 455. The laminate 450 may comprise a laminate redistribution layer (RDL) 452 structured to route signals between upper and lower surfaces of the laminate 450. When the IC die 405 is attached to the laminate 450 (e.g., through soldering), the active devices 410, 420 may be electrically coupled with the laminate RDL 452 through the interconnects 448 and through the metallization layers and vias within the routing layer 425. At the lower surface of the laminate 450, the laminate RDL 452 may be coupled to (e.g., in contact with) ground connects 457 or signal connects 459 (power connect not illustrated for brevity). It is of course expected that the laminate RDL 452 is structured so as to prevent electrical shorts between ground connects 457, the signal connects 459, and the unillustrated power connects.

The IC die 405 may also comprise a thermal spreader 415 on the active devices 410, 420. The IPDs 430, 440 may be within a routing layer 425 under the spreader 415. The thermal spreader 415 may be thermally conductive and electrically insulative. For example, the thermal spreader 415 may be a diamond layer. Thus, in an aspect, the IC die 405 may also be referred to as a silicon-on-diamond (SOD) die. Optionally, the IC die 405 may include a silicon (Si) layer 412 on the thermal layer 415. When included, the upper surface of the Si layer 412 may coincide with the upper surface of the IC die 405 as a whole. Otherwise, the upper surface of the thermal layer 415 may coincide with the upper layer of the IC die 405.

A mold 460 may be formed on the laminate 450 and on the IC die 405. In particular, the mold 460 may include a side mold part 462 and a lateral mold part 464. The side mold part 462 may be on the upper surface of the laminate 450 and on the side surfaces of the IC die 405. Also, the lateral mold part 464 may be on the side mold part 462 and on the upper surface of the IC die 405. Thus, it may be said that the mold 460 is structured to surround the side and the upper surfaces of the IC die 405. The lateral and side mold parts 464, 462 may be formed from same or different materials. When formed from the same materials, they may be integrally formed.

A cage 470 may be formed within the mold 460. The cage 470 may be formed from thermally conductive materials. In an aspect, the cage 470 may also be electrically conductive (e.g., metals). The cage 470 may be structured to channel heat generated by the active devices 410, 420 through thermal paths that do not go through the metallization layers and vias of the routing layer 425. In FIG. 4A, the heat at the hotspots, which are heat that emanates through the thermal spreader 415 above the upper surface of the IC die 405, are illustrated with thickly dashed arrows as being conducted laterally towards the side. That is, the cage 460 may be structured to conduct the heat from an interior of the IC die boundary 477 to an exterior of the IC die boundary above the upper surface of the IC die 405. The heat then may be conducted downwardly towards the laminate 450. In this way, the heat dissipation characteristics of the package 400 can be significantly improved.

The cage 470 may include a lateral cage part 474 and a side cage part 472. The lateral cage part 474 may be formed within the lateral mold part 464 and structured to perform the lateral heat conduction. That is, the lateral cage part 474 may conduct the heat emanating through the thermal spreader 415 above the upper surface of the IC die (405) from the interior to the exterior of the IC die boundary 477.

The side cage part 472 may be formed within the side mold part 462 and structured to perform the downward heat conduction. That is, the lateral cage part 474 may be structured such that such that the heat conducted to the exterior of the IC die boundary 477 by the lateral cage part 474 is conducted to the laminate 450 by the side cage part 472. For example, the side cage part 472 may be in contact with the lateral cage part 474. In an aspect, the side cage part 472 may be thermally and/or electrically coupled with the laminate RDL 452.

The lateral and side cage parts 474, 472 may be formed from same or different materials. When formed from the same materials, they may be integrally formed. For example, the lateral and/or the side cage parts 474, 472 may be formed from thermally and/or electrically conductive metals such as copper (Cu).

As indicated above, the side cage part 472 may be formed within the side mold part 462. In an aspect, the side cage part 472 may comprise any number of through-mold-vias (TMVs) 473. This is illustrated in FIG. 4B, which may be considered to be a side view of the package 400. As seen, one or more TMVs 473 may be formed within the side mold part 462. The TMVs 473 may be thermally coupled with (e.g., in contact with) the laminate RDL 452. The TMVs 473 may provide multiple thermal paths external to the IC die 405 to channel heat away from the IC die 405.

In an aspect, when the side cage part 472 is electrically ground (which means the cage 470 is grounded), the cage 470 may also serve as a shield to guard against electromagnetic interference (EMI). For example, as seen in FIG. 4B, the side cage part 472 may be grounded through the laminate RDL 452 in connection with the ground connect 457. When this occurs, the cage 470 may protect the active devices 410, 420 from overheating, and may also shield them from internal EMI (one active device interfering with another active device within the IC die 405) and/or from external EMI (interference from sources external to the IC die 405).

FIGS. 4C, 4D, and 4E, which may be considered to be top views of the package 400, illustrate examples of shapes of the lateral cage part 474. These are merely examples, i.e., the lateral cage part 474 may take on a variety of shapes. In FIGS. 4C, 4D, and 4E, it may be assumed that the long-dashed rectangle represents the boundary of the IC die 405. It may also be assumed that the short-dashed ovals represent areas occupied by the active devices 410, 420 and IPDs 440 (e.g., inductor).

FIG. 4C illustrates an example in which the lateral cage part 474 is formed as a mesh. The lateral cage part 474 may provide thermal paths (thick dashed arrows) to channel the heat generated by the active devices 410 from the interior of the IC die boundary 477 to the exterior of the IC die boundary 477. For the purposes of channeling heat, it may be desirable to maximize vertical overlap between the lateral cage part 474 and the active devices 410, 420. This is illustrated in FIG. 4D which shows the lateral cage part 474 as a solid piece (no holes). As seen, the solid lateral cage part 474 can vertically overlap with the entirety of the active devices 410, 420.

Maximizing vertical overlap with the active devices 410, 420 may also be beneficial for EMI shielding purposes. However, vertically overlapping the solid lateral cage part 474 with the IPD 440 (e.g., an inductor) may actually be undesirable to the performance of the IPD 440 due to the active devices 410, 420 inducing eddy currents in the lateral cage part 474. The undesirable effects can become pronounced as the active devices 410, 420 operate in high frequencies such as 5G NR frequencies. To mitigate such effects, it may be desirable to minimize vertical overlap between the lateral cage part 474 and the IPD 440. This is illustrated in FIG. 4E in which the lateral cage part 474 includes a hole such that there is no vertical overlap between the IPD 440 and the lateral cage part 474.

As mentioned, shapes of the lateral cage part 474 illustrated in FIGS. 4C, 4D, and 4E are merely examples. The lateral cage part 474 may be shaped to include solid portions and holes such as the mesh. In an aspect, the lateral cage part 474 may be characterized generally as follows. The lateral cage part 474 may be formed or shaped such that at least a portion of the lateral cage part 474 vertically overlaps with at least a portion of at least one active device 410, 420. Alternatively or in addition thereto, the lateral cage part 474 may be formed or shaped such that at least a portion of the lateral cage part 474 does not vertically overlap with at least a portion of at least one IPD 440.

Recall from above that the IC die 405 may include the Si layer 412 on the thermal layer 415, i.e., in between the thermal layer 415 and the mold 460, which is illustrated in FIG. 4A. In particular, the Si layer 412 may be in between the thermal layer 415 and the lateral cage part 474 of the cage 470. Thermal conductivity of Si layer 412 is good, but not as good as the diamond thermal layer 415. Thus, in some instances, the presence of the Si layer 412 may inhibit heat transfer in the direction from the thermal layer 415 to the lateral cage part 474, especially when the Si layer 412 is thick (e.g., 1-2 mils or greater).

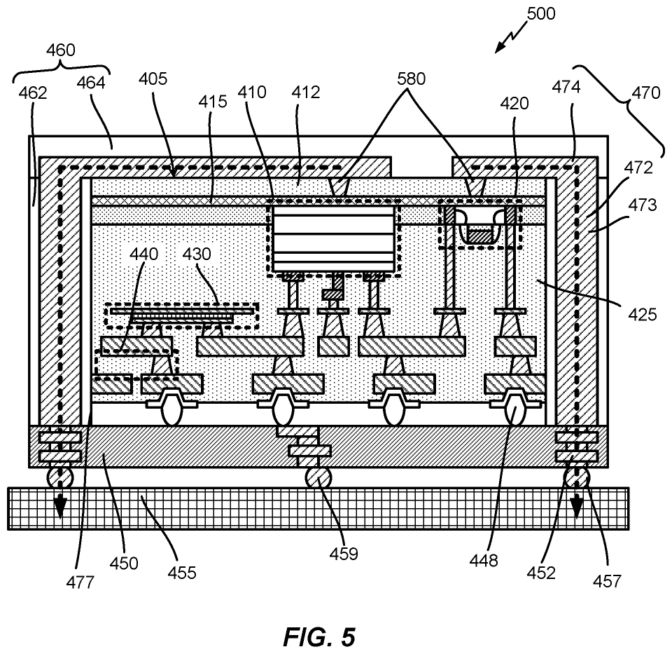

Thus, as seen in FIG. 5 illustrating a package 500, one or more through-silicon-vias (TSVs) 580 may be formed in the Si layer 412. The TSVs 580 may be formed from conductive materials such as Cu. The TSVs 580 may be formed to vertically overlap with the active devices 410, 420. More generally, at least one TSV 580 may vertically overlap with at least a portion of at least one active device 410, 420. The TSVs 580 may be in contact with the cage 470, e.g., in contact with the lateral cage part 474. This can maximize heat conductance between the TSVs 580 and the cage 470. As long as the thermal layer 415 is in between the active devices 410, 420 and the TSVs 580, electrical shorts between the cage 470 and the active devices 410, 420 can be minimized or prevented altogether. In an aspect, the TSVs 580 may be formed when the Si layer 412 is thicker than a threshold thickness (e.g., thicker than 1 mil).

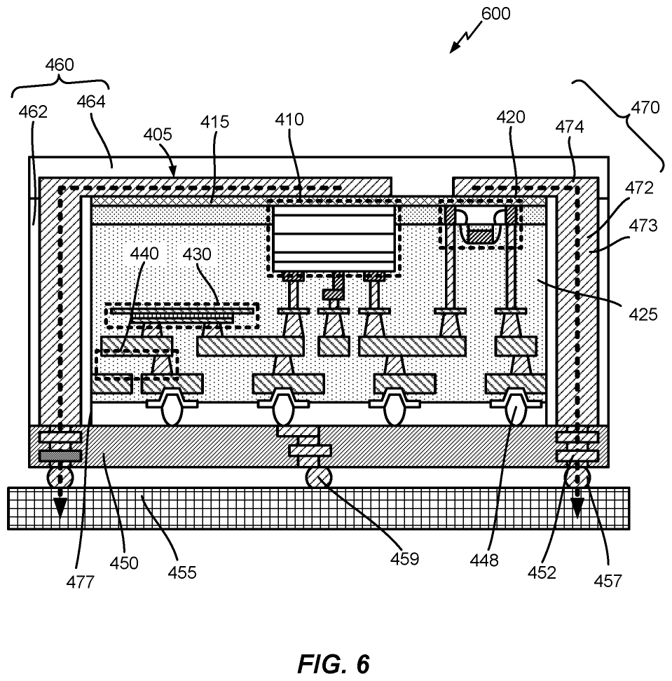

Since the Si layer 412 is options, the IC die 405 may not include the Si layer 412 as seen in FIG. 6 illustrating a package 600. In this instance, the upper surface of the thermal layer 415 may coincide with the upper layer of the IC die 405, and the lateral mold part 464 and the lateral cage part 474 may be formed on the thermal layer 415. In particular, the lateral cage part 474 may be in contact with the thermal layer 415. Since the thermal layer 415 is electrically resistive, electrical shorts between the cage 470 and the active devices 410, 420 can be minimized or prevented altogether. Also due to the high thermal conductivity of the thermal layer 415, a high amount of heat may be conducted through the cage 470.

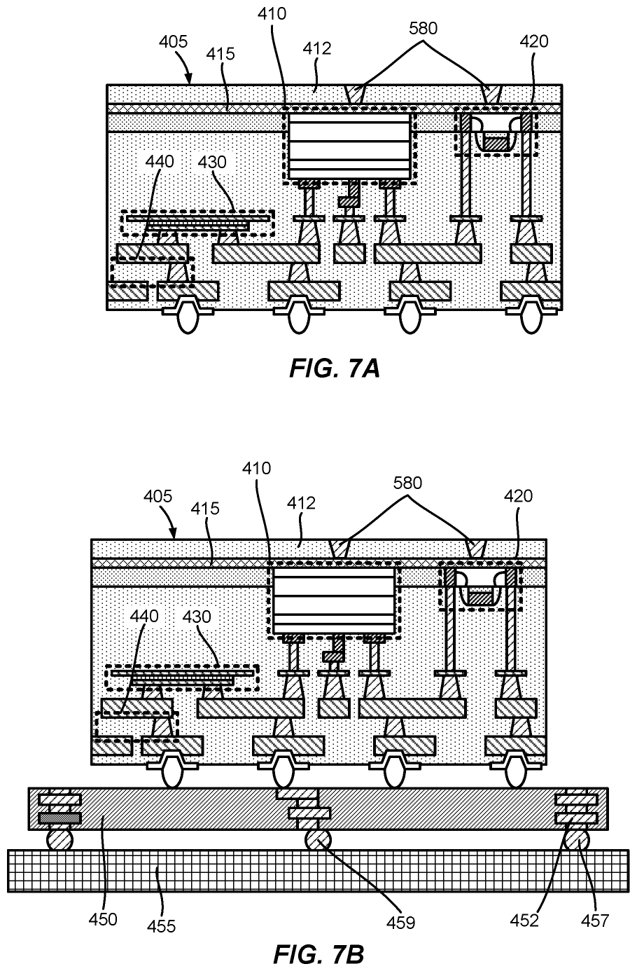

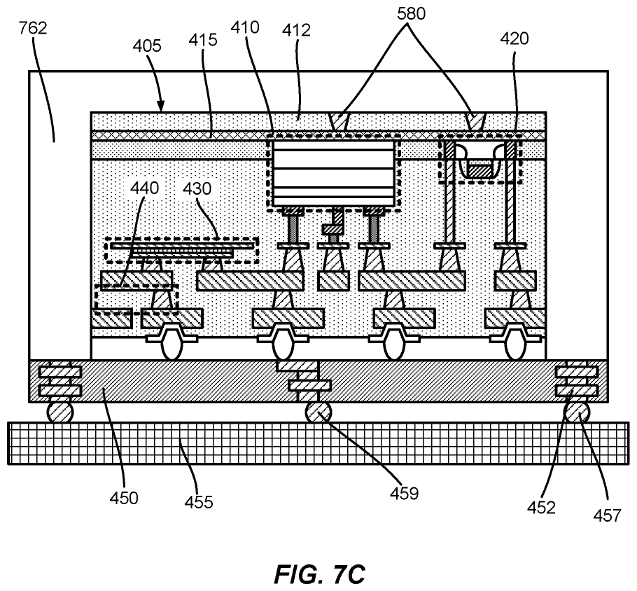

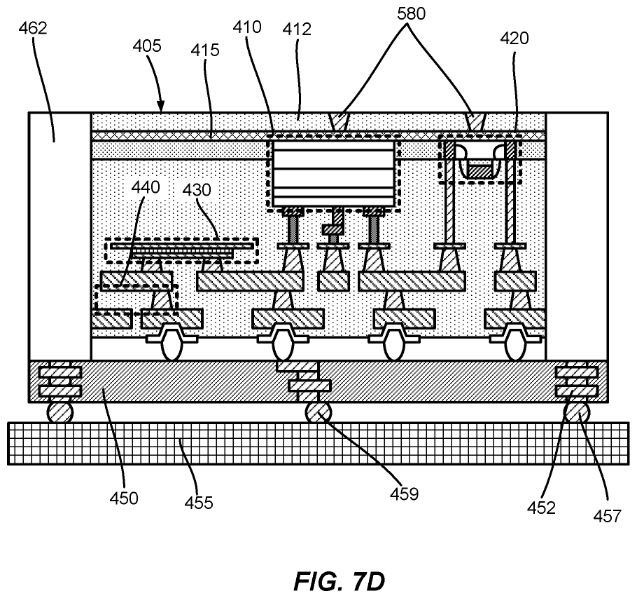

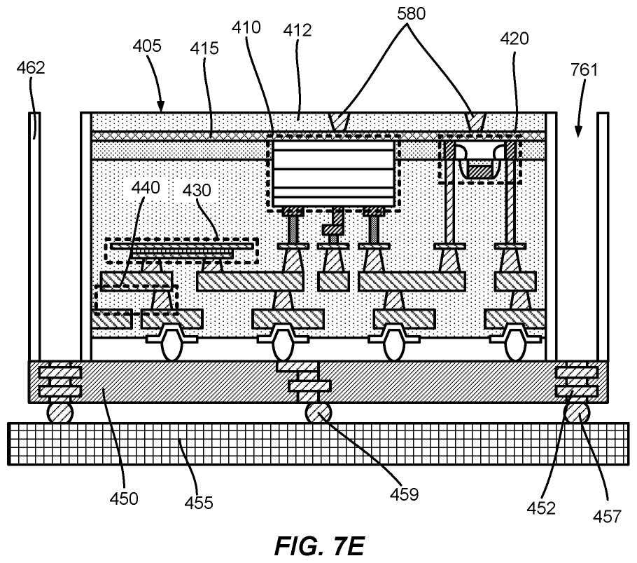

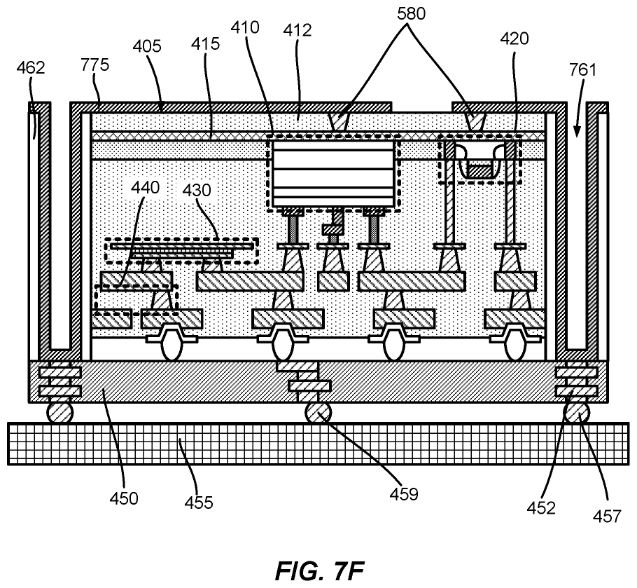

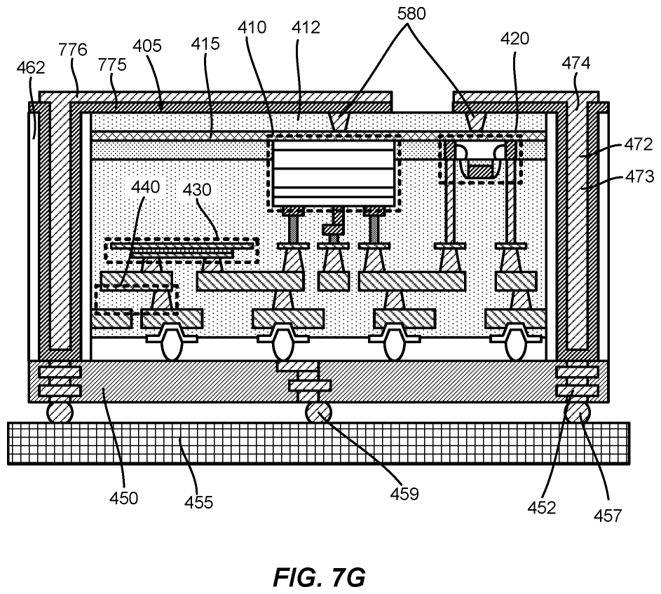

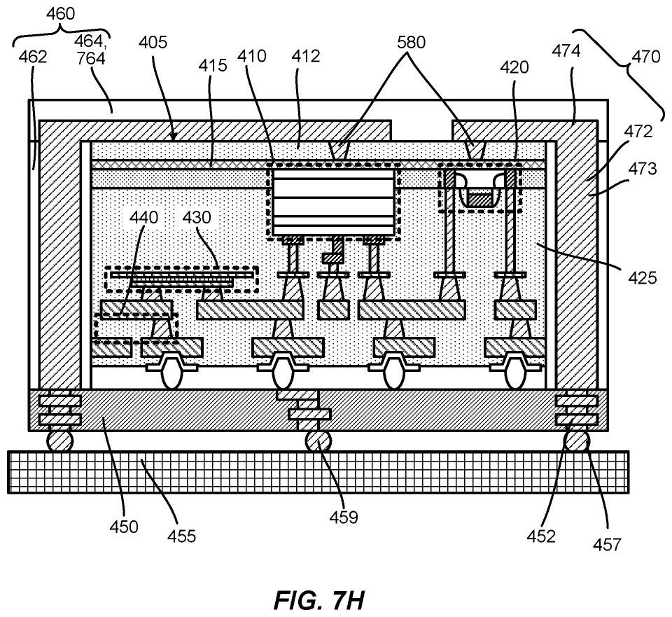

FIGS. 7A-7H illustrate examples of different stages of fabricating the package 500 illustrated in FIG. 5. While stages of fabricating the package 500 are shown, it will be readily apparent that other than FIG. 7A, the illustrated stages are applicable to fabricating the packages 400 and 600 of FIGS. 4A and 6.

FIG. 7A illustrates an example of a stage in which the TMVs 580 may be formed within the Si layer 412 of the IC die 405, which may be one of multiple IC dies 405 of a wafer. While not illustrated, in an aspect, the TMVs 580 may be formed prior to the IC die 405 being singulated from the wafer of IC dies 405. As mentioned above, the TMVs 580 may be formed when the thickness of the Si layer 412 is greater a threshold thickness. The TMVs 580 may be formed by forming openings in the Si layer 412 and depositing conductive material such as Cu in the openings. If desired, the Si layer 412 and/or the deposited conductive material may be planarized (e.g., CMP) such that the upper surfaces of the Si layer 412 and the TMVs 580 are coplanar. The stage of FIG. 7A may not be applicable to packages 400 and 600 (of FIGS. 4A and 6) since there are no TMVs 580 in those packages.

FIG. 7B illustrates an example stage in which the IC die 405 may be singulated, picked and placed (e.g., so called PnP process) onto the laminate 450, and attached to the laminate 450. In detail, the IC die 405 may be a singulated die from a wafer of IC dies 405. When the singulated IC die 405 is picked and placed, the IC die 405 may be flipped so as to be oriented with the lower surface—the surface opposite to the Si layer 412 (or opposite to the thermal layer 415)—faces the laminate 450. The IC die 405 may be attached to the laminate 450 through soldering the interconnects 448 at the lower surface of the IC die 405 to the laminate RDL 452. After attaching, the active devices 410, 420 may be electrically coupled with the laminate RDL 452 through the interconnects 448.

FIG. 7C illustrates an example stage in which a first mold compound 762 may be deposited on the laminate 450 and on the IC die 405 such that the side and upper surfaces of the IC die 405 are covered.

FIG. 7D illustrates an example stage in which the first mold compound 762 may be planarized (e.g., CMP) to form the side mold part 462. Planarizing the first mold compound 762 may expose the upper surface of the IC die 405. That is, the upper surfaces of Si layer 412 and the TMVs 580 may be exposed. However, for the package 400 of FIG. 4A, this may correspond to exposing the upper surface of Si layer 412, and for the package 600 of FIG. 6, this may correspond to exposing the upper surface of thermal layer 415.

FIG. 7E illustrates an example stage in which mold openings 761 may be formed in the side mold part 462. The mold openings 761 may expose corresponding laminate RDLs 452 on the upper surface of the laminate 450.

FIG. 7F illustrates an example stage in which a seed layer 775 may be deposited in the mold openings 761 and on the IC die 405. For example, TiW may be used as the material for the seed layer 775. In an aspect, the seed layer 775 may be electrically grounded through the laminate RDL 452.

FIG. 7G illustrates an example stage in which a conductive layer 776 may be plated on the seed layer 775. For example, Cu may be used as the material for the plated conductive layer 776. The seed layer 775 and the plated conductive layer 776 may form the cage 470. That is, the seed layer 775 and the plated conductive layer 776 that fill the mold openings 761 may form the side cage part 472, and the seed layer 775 and the plated conductive layer 776 deposited over the IC die 405 may form the lateral cage part 474. When the seed layer 775 is electrically grounded, then the resulting cage 470 formed by the seed layer 775 and the plated conductive layer 776 may also serve as the EMI shield.

It should be noted that the seed layer 775 is not strictly necessary. That is, the materials for the conductive layer 776 may be formed in the mold openings 761 and on the IC die 405 without the seed layer 775. This is illustrated in the example packages 400, 500, 660 in FIGS. 4A, 5, and 6. In this instance, the conductive layer 776 may be electrically grounded through the laminate RDL 472 to serve as the EMI shield as well as to provide thermal paths to channel the heat from the active devices 410, 420.

FIG. 7H illustrates an example stage in which a second mold compound 764 may be deposited on the conductive layer 776, i.e., on the lateral cage part 474. The deposited second mold compound 764 may be planarized, e.g., through CMP, to form the lateral mold part 464. The material for the second mold compound 764 may be the same or different from the material for the first mold compound 762.

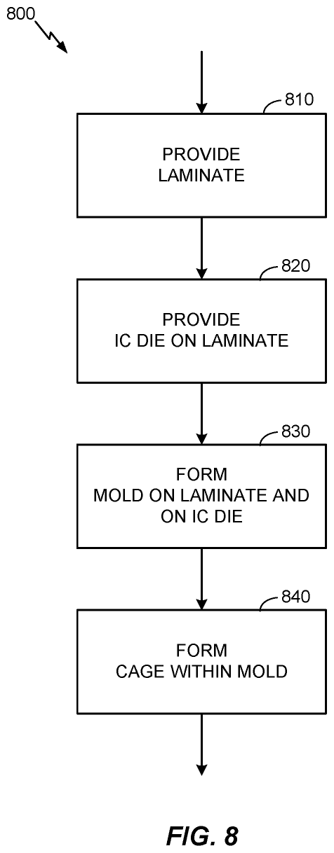

FIG. 8 illustrates a flow chart of an example method of fabricating a package such as the packages 400, 500, 600 of FIGS. 4A, 5 and 6. In block 810, the laminate 450 may be provided. In block 820, the IC die 405 may be provided on the laminate 450.

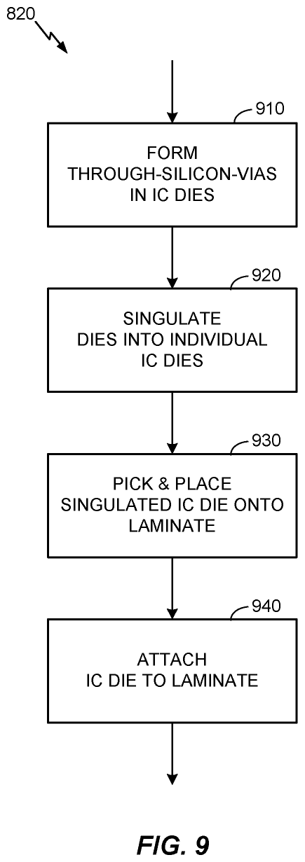

FIG. 9 illustrates a flow chart of an example process to implement block 820. In block 910, TMVs 580 may be formed in the Si layer 412 of the IC die 405. Block 910 may correspond to the stage illustrated in FIG. 7A. Note that block 910 is optional. For example, block 910 may be performed if the Si layer 412 is relatively thick (e.g., at least the threshold thickness). Otherwise, block 910 may be skipped. Block 910 may also be skipped if the IC die 405 does not include the Si layer 412. In an aspect, if block 910 is performed, it may be performed prior to singulating the wafer of IC dies 405.

In block 920, the wafer of IC dies 405 may be singulated to individual IC dies. In block 930, the singulated IC die 405 may be picked and placed onto the laminate 450. For example, the IC die 405 may be oriented with the lower surface thereof faces the laminate 450. In block 940, the IC die 405 may be attached to the laminate 450, e.g., by soldering the interconnects 448 at the lower surface of the IC die 405 to the laminate RDL 452. After attaching, the active devices 410, 420 may be electrically coupled with the laminate RDL 452 through the interconnects 448. Blocks 920, 930 and 940 may correspond to the stage illustrated in FIG. 7B.

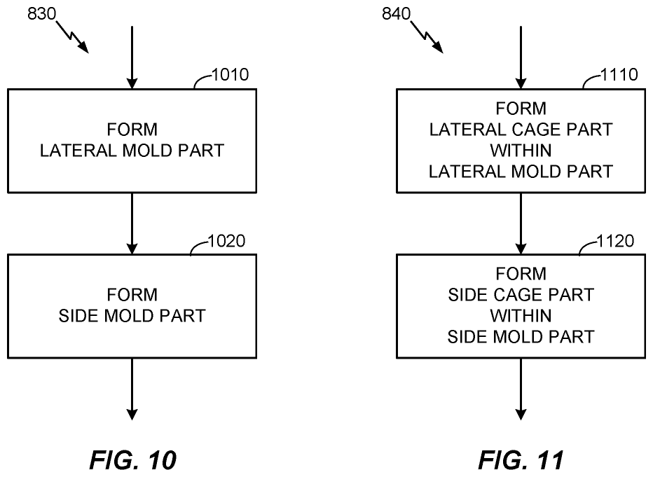

Referring back to FIG. 8, in block 830, the mold 460 may be formed on the laminate 450 and on the IC die 405 such that the mold 460 surrounds the side and upper surfaces of the die 405. FIG. 10 illustrates a flow chart of an example process to implement block 830. In block 1010, the lateral mold part 464 may be formed on the upper surface of the IC die 405. In block 1020, the side mold part 462 may be formed on the upper surface of the laminate 450 and on the side surfaces of the IC die 405.

Referring back to FIG. 8, in block 840, the cage 470 may be formed in the mold 460. The cage 470 may be formed to conduct the heat generated by the active devices 410, 420 emanating through the thermal spreader 415 above the upper surface of the IC die 405 from interior to exterior of the IC die boundary 477.

FIG. 11 illustrates a flow chart of an example process to implement block 840. In block 1110, the lateral cage part 474 may be formed within the lateral mold part 464, and the lateral cage part 474 may conduct the heat from interior to exterior of the IC die boundary 477. In block 1120, the side cage part 472 may be formed within the side mold part 462. The side cage part 472 may be in contact with the lateral cage part 474 such that the heat conducted to the exterior of the IC die boundary 477 by the lateral cage part 474 is conducted to the laminate 450 by the side cage part 472. The lateral and side cage parts 474, 472 may be formed from same or different materials. When formed from the same materials, they may be integrally formed.

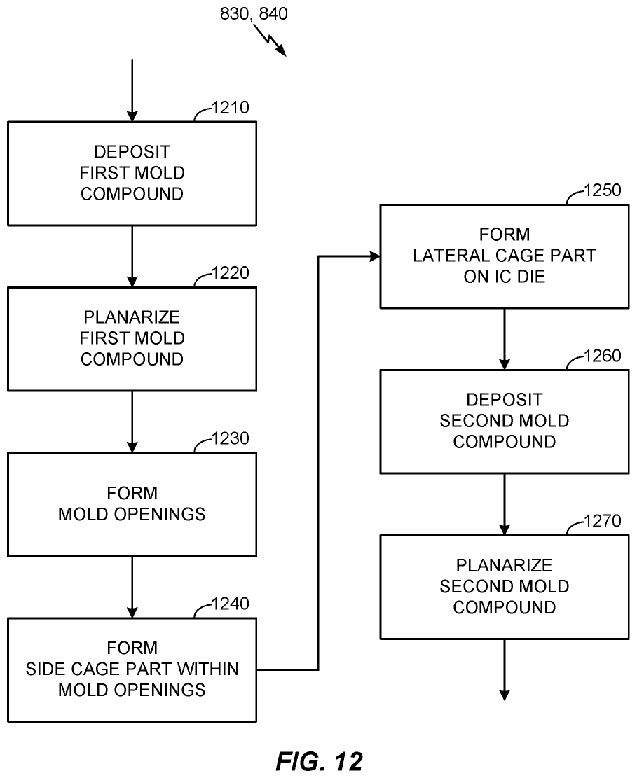

FIG. 12 illustrates a flow chart of an example process to implement blocks 1010, 1020, 1110 and 1120. In block 1210, the first mold compound 762 may be deposited on the laminate 450 and on the IC die 405. Block 1210 may correspond to the stage illustrated in FIG. 7C.

In block 1220, the first mold compound 762 may be planarized (e.g., CMP) to form the side mold part 462. Planarizing the first mold compound 762 may expose the upper surface of the IC die 405. Block 1220 may correspond to the stage illustrated in FIG. 7D.

In block 1230, the mold openings 761 may be formed in the side mold part 462. The mold openings 761 may expose corresponding laminate RDLs 452 on the upper surface of the laminate 450. Block 1230 may correspond to the stage illustrated in FIG. 7E.

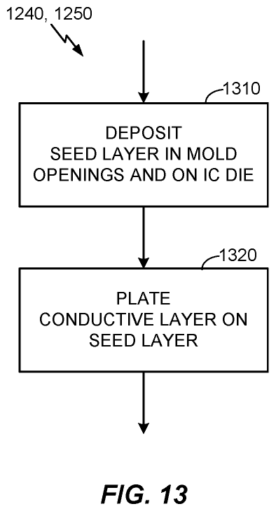

In block 1240, the side cage part 472 may be formed within the mold openings 761. In block 1250, the lateral cage part 474 may be formed on the IC die. FIG. 13 illustrates a flow chart of an example process to implement blocks 1240, 1250. In block 1310, the seed layer 775 may be deposited in the mold openings 761 and on the IC die 405. Block 1310 may correspond to the stage illustrated in FIG. 7F. In block 1320, the conductive layer 776 may be plated on the seed layer 775. Block 1320 may correspond to the stage illustrated in FIG. 7G. The side cage part 472 may comprise the TMVs 473 formed by the seed layer 775 and the plated conductive layer 776 formed in the mold openings 761. The lateral cage part 474 may comprise the seed layer 775 and the plated conductive layer 776 formed on the IC die 405.

Again, it is noted that block 1310 may not be strictly necessary. That is, block 1320 may be performed to form the cage 470, i.e., to form the lateral cage part 474 and the side cage part 472. In this instance, the side cage part 472 may comprise the TMVs 473 formed by the conductive layer 776 in the mold openings 761, and the lateral cage part 474 may comprise the conductive layer 776 formed on the IC die 405.

Referring back to FIG. 12, in block 1260, the second mold compound 764 may be deposited on the on the lateral cage part 474. In block 1270, the deposited second mold compound 764 may be planarized, e.g., through CMP, to form the lateral mold part 464. The material for the second mold compound 764 may be the same or different from the material for the first mold compound 762. Blocks 1260 and 1270 may correspond to the stage illustrated in FIG. 7H.

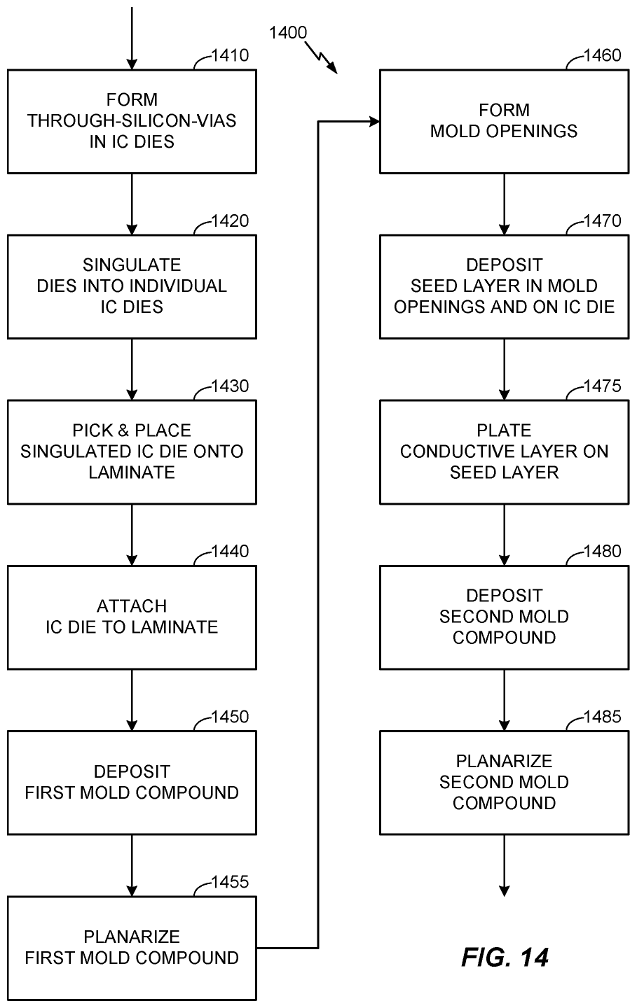

FIG. 14 illustrates a flow chart of another example method of fabricating a package such as the packages 400, 500, 600 of FIGS. 4A, 5, 6. In block 1410, the TMVs 580 may be formed in the Si layer 412 of the IC die 405. Block 1410 may correspond to the stage illustrated in FIG. 7A. Again, it is to be noted that block 1410 may be optional.

In block 1420, the wafer of IC dies 405 may be singulated to individual IC dies. In block 1430, the singulated IC die 405 may be picked and placed onto the laminate 450. In block 1440, the IC die 405 may be attached to the laminate 450. Blocks 1420, 1430 and 1440 may correspond to the stage illustrated in FIG. 7B.

In block 1450, the first mold compound 762 may be deposited on the laminate 450 and on the IC die 405. Block 1450 may correspond to the stage illustrated in FIG. 7C. In block 1460, the first mold compound 762 may be planarized (e.g., CMP) to form the side mold part 462. Block 1460 may correspond to the stage illustrated in FIG. 7D.

In block 1460, the mold openings 761 may be formed in the side mold part 462. Block 1460 may correspond to the stage illustrated in FIG. 7E. In block 1470, the seed layer 775 may be deposited in the mold openings 761 and on the IC die 405. Block 1470 may correspond to the stage illustrated in FIG. 7F. In block 1475, the conductive layer 776 may be plated on the seed layer 775. Block 1475 may correspond to the stage illustrated in FIG. 7G. Block 1470 may not be strictly necessary. That is, block 1475 may be performed to deposit the conductive layer 775 within the mold openings 761 and on the IC die 405.

In block 1480, the second mold compound 764 may be deposited on the on the lateral cage part 474. In block 1485, the deposited second mold compound 764 may be planarized, e.g., through CMP, to form the lateral mold part 464. Blocks 1480 and 1485 may correspond to the stage illustrated in FIG. 7H.

It should be noted that not all illustrated blocks of FIGS. 8-14 need to be performed, i.e., some blocks may be optional. Also, the numerical references to the blocks of these figures should not be taken as requiring that the blocks should be performed in a certain order.

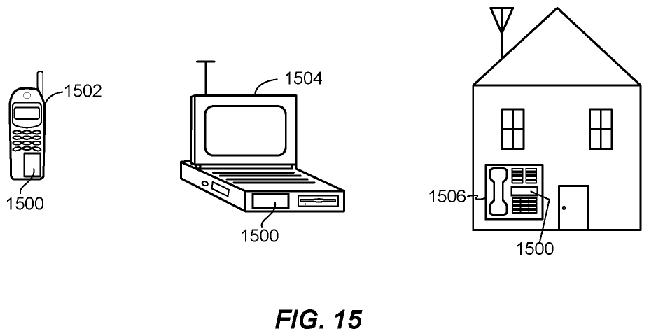

FIG. 15 illustrates examples of devices with a package integrated therein. FIG. 15 illustrates various electronic devices that may be integrated with any of the aforementioned packages 400, 500, 600. For example, a mobile phone device 1502, a laptop computer device 1504, a terminal device 1506 as well as wearable devices, portable systems, that require small form factor, extreme low profile, may include a device/package 1500 that incorporates any of the packages 400, 500, 600 as described herein. The device/package 1500 may be, for example, any of the integrated circuits, dies, integrated devices, integrated device packages, integrated circuit devices, device packages, integrated circuit (IC) packages, package-on-package devices, system in package devices described herein. The devices 1502, 1504, 1506 illustrated in FIG. 15 are merely exemplary. Other electronic devices may also feature the device/package 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the examples disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled with the processor such that the processor can read information from, and write information to, the storage medium. In the alternative, the storage medium may be integral to the processor.

Accordingly, an aspect can include a computer readable media embodying a method of forming a semiconductor device. Accordingly, the scope of the disclosed subject matter is not limited to illustrated examples and any means for performing the functionality described herein are included.

While the foregoing disclosure shows illustrative examples, it should be noted that various changes and modifications could be made herein without departing from the scope of the disclosed subject matter as defined by the appended claims. The functions, processes and/or actions of the method claims in accordance with the examples described herein need not be performed in any particular order. Furthermore, although elements of the disclosed subject matter may be described or claimed in the singular, the plural is contemplated unless limitation to the singular is explicitly stated.

What is claimed is:

1. A package, comprising:
a laminate comprising a laminate redistribution layer (RDL);
an integrated circuit (IC) die on the laminate and comprising
one or more active devices above a lower surface of the IC die and electrically coupled with the laminate RDL through one or more interconnects at the lower surface of the IC die, and
a thermal spreader on the one or more active devices, the thermal spreader being thermally conductive and electrically insulative;
a mold on the laminate and on the IC die, the mold structured to surround side and upper surfaces of the IC die; and
a cage within the mold, the cage structured to conduct heat generated by the one or more active devices emanating through the thermal spreader above an upper surface of the IC die from an interior of an IC die boundary to an exterior of the IC die boundary.

2. The package of claim 1, wherein the thermal spreader is a diamond layer.

3. The package of claim 1,
wherein the mold comprises
a lateral mold part on the upper surface of the IC die, and
a side mold part on an upper surface of the laminate and on the side surfaces of the IC die, and
wherein the cage comprises
a lateral cage part within the lateral mold part, the lateral cage part structured to conduct the heat emanating through the thermal spreader above the upper surface of the IC die from the interior of the IC die boundary to the exterior of the IC die boundary, and
a side cage part within the side mold part, the side cage part in contact with the lateral cage part such that the heat conducted to the exterior of the IC die boundary by the lateral cage part is conducted to the laminate by the side cage part.

4. The package of claim 3, wherein the side cage part and/or the lateral cage part are formed of copper (Cu).

5. The package of claim 3, wherein the side cage part comprises one or more through-mold-vias (TMV).

6. The package of claim 3, wherein the lateral cage part is formed as a mesh.

7. The package of claim 3, wherein at least a portion of the lateral cage part vertically overlaps at least a portion of at least one active device.

8. The package of claim 3, wherein the side cage part is electrically grounded through the laminate RDL such that the cage forms an electromagnetic interference (EMI) shield to shield the IC die.

9. The package of claim 8,
wherein the IC die further comprises one or more integrated passive devices below the thermal spreader, and
wherein at least a portion of the lateral cage part does not vertically overlap at least a portion of at least one IPD.

10. The package of claim 1, wherein the IC die further comprises a silicon (Si) layer vertically in between the thermal spreader and the cage.

11. The package of claim 10, wherein the IC die further comprises one or more through-silicon-vias (TSV) within the Si layer such that at least one TSV is in contact with the cage and vertically overlaps at least a portion of at least one active device.

12. The package of claim 1, wherein the one or more active devices comprise a first active device and a second active device, the first active device being a device of a first technology and the second active device being a device of a second technology different from the first technology.

13. The package of claim 12, wherein the first technology is a group III-V technology and the second technology is a silicon (Si)-based technology.

14. The package of claim 1, wherein the package is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

15. A method, comprising:
providing a laminate comprising a laminate redistribution layer (RDL);
providing an integrated circuit (IC) die on the laminate, the IC die comprising
one or more active devices above a lower surface of the IC die and electrically coupled with the laminate RDL through one or more interconnects at the lower surface of the IC die, and
a thermal spreader on the one or more active devices, the thermal spreader being thermally conductive and electrically insulative;
forming a mold on the laminate and on the IC die such that the mold surrounds side and upper surfaces of the IC die; and
forming a cage within the mold such that the cage conducts heat generated by the one or more active devices emanating through the thermal spreader above an upper surface of the IC die from an interior of an IC die boundary to an exterior of the IC die boundary.

16. The method of claim 15, wherein the thermal spreader is a diamond layer.

17. The method of claim 15,
wherein forming the mold comprises:
forming a lateral mold part on the upper surface of the IC die; and
forming a side mold part on an upper surface of the laminate and on the side surfaces of the IC die, and
wherein forming the cage comprises:
forming a lateral cage part within the lateral mold part such that the lateral cage part conducts the heat emanating through the thermal spreader above the upper surface of the IC die from the interior of the IC die boundary to the exterior of the IC die boundary; and
forming a side cage part within the side mold part to be in contact with the lateral cage part such that the heat conducted to the exterior of the IC die boundary by the lateral cage part is conducted to the laminate by the side cage part.

18. The method of claim 17, wherein forming the mold and forming the cage comprise:
depositing a first mold compound on the IC die and on the laminate;
planarizing the first mold compound to form the side mold part, the upper surface of the IC die being exposed after planarizing;
forming one or more mold openings in the side mold part;
forming the side cage part within the one or more mold openings;
forming the lateral cage part on the IC die;
depositing a second mold compound on the side and lateral cage parts, the IC die and the side mold part; and
planarizing the second mold compound to form the lateral mold part.

19. The method of claim 18, wherein forming the side cage part and forming the lateral cage part comprise:
depositing a seed layer in the one or more mold openings and on the IC die; and
plating a conductive layer on the seed layer,
wherein the side cage part comprises one or more through-mold-vias (TMV) formed by the seed and conductive layers in the one or more mold openings, and
wherein the lateral cage part comprises the seed and seed and conductive layers formed on the IC die.

20. The method of claim 17, wherein the side cage part and/or the lateral cage part are formed of copper (Cu).

21. The method of claim 17, wherein the lateral cage part is formed as a mesh.

22. The method of claim 17, wherein at least a portion of the lateral cage part is formed to vertically overlap at least a portion of at least one active device.

23. The method of claim 17, wherein the side cage part is formed to be electrically grounded through the laminate RDL such that the cage forms an electromagnetic interference (EMI) shield to shield the IC die.

24. The method of claim 23,
wherein the IC die further comprises one or more integrated passive devices below the thermal spreader, and
wherein the lateral cage part is formed such that for at least one IPD, at least a portion of the at least one IPD does not vertically overlap with at least a portion of the lateral cage part.

25. The method of claim 15, wherein providing the IC die on the laminate comprises:
singulating a wafer of IC dies into individual IC dies;
picking and placing the singulated IC die onto the laminate; and
attaching the IC die to the laminate.

26. The method of claim 25, wherein the IC die further comprises a silicon (Si) layer vertically in between the thermal spreader and the cage.

27. The method of claim 26, wherein providing the IC die on the laminate further comprises:
forming one or more through-silicon-vias (TSVs) within the Si layer such that the at least one TSV is in contact with the cage and vertically overlaps at least a portion of at least one active device.

28. A method, comprising:
singulating a wafer of integrated circuit (IC) dies into individual IC dies, each IC die comprising
one or more active devices above a lower surface of the IC die, and
a diamond thermal spreader on the one or more active devices, the thermal spreader being thermally conductive and electrically insulative;
picking and placing an IC die onto a laminate, the laminate comprising a laminate redistribution layer (RDL);
attaching the IC die to the laminate such that the one or more active devices are electrically coupled with the laminate RDL through one or more interconnects at the lower surface of the IC die;
depositing a first mold compound on the IC die and on the laminate;
planarizing the first mold compound to form a side mold part, the upper surface of the IC die being exposed after planarizing;
forming one or more mold openings in the side mold part;
depositing a seed layer in the one or more mold openings and on the IC die;
plating a conductive layer on the seed layer;
depositing a second mold compound on the conductive layer, the IC die, and the side mold part; and
planarizing the second mold compound to form a lateral mold part,
wherein the seed layer and the plated conductive layer form a cage comprising
a lateral cage part within the lateral mold part, the lateral cage part structured to conduct heat generated by the one or more active devices emanating through the thermal spreader above an upper surface of the IC die from an interior of an IC die boundary to an exterior of the IC die boundary, and
a side cage part within the side mold part, the side cage part in contact with the lateral cage part such that the heat conducted to the exterior of the IC die boundary by the lateral cage part is conducted to the laminate by the side cage part.

29. The method of claim 28, wherein at least a portion of the lateral cage part is formed to vertically overlap at least a portion of at least one active device.

30. The method of claim 28, wherein the side cage part is formed to be electrically grounded through the laminate RDL such that the cage forms an electromagnetic interference (EMI) shield to shield the IC die.
